(19) United States
(12) Patent Application Publication
(10) Pub. No.: US 2024/0334673 A1
(43) Pub. Date: Oct. 3, 2024

(54) SEMICONDUCTOR DEVICE AND METHOD OF FABRICATING THE SAME

(71) Applicant: Samsung Electronics Co., Ltd., Suwon-si (KR)

(72) Inventors: Ki Seok LEE, Suwon-si (KR); Hong Jun LEE, Suwon-si (KR); Hyun Geun CHOI, Suwon-si (KR); Keun Nam KIM, Suwon-si (KR); In Cheol NAM, Suwon-si (KR); Bo Won YOO, Suwon-si (KR); Jin Woo HAN, Suwon-si (KR)

(21) Appl. No.: 18/518,687

(22) Filed: Nov. 24, 2023

(30) Foreign Application Priority Data
Mar. 28, 2023 (KR) 10-2023-0040451

(51) Int. Cl. H10B 12/00

(52) U.S. Cl. CPC H10B 12/038; H10B 12/482; H10B 12/488

(57) ABSTRACT

A semiconductor device includes a lower substrate, a memory cell structure including a wordline on the lower substrate, a bitline disposed on the lower substrate and intersecting the wordline, and a cell capacitor connected to the lower substrate, an upper substrate having a back side adjacent to the lower substrate and a front side opposite to the back side, a circuit element disposed on the front side of the upper substrate and overlapping the memory cell structure in a vertical direction, and a through via penetrating the upper substrate and electrically connecting the memory cell structure and the circuit element with each other.

### CROSS-REFERENCE TO RELATED APPLICATION

This application claims priority from Korean Patent Application No. 10-2023-0040451 filed on Mar. 28, 2023, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device and a method of fabricating the same, and more particularly, to a semiconductor memory device including capacitors and a method of fabricating the same.

### 2. Description of the Related Art

As semiconductor memory devices have increasingly become highly integrated, individual circuit patterns have increasingly become miniaturized to implement more semiconductor memory devices in each given area. The miniaturization of individual circuit patterns, however, increases processing difficulty and causes defects. Accordingly, various methods have been studied to fabricate semiconductor devices with excellent performance while overcoming limitations associated with the integration of semiconductor devices.

### SUMMARY

Aspects of the present disclosure provide a semiconductor device with an improved degree of integration.

Aspects of the present disclosure also provide a method of fabricating a semiconductor device with an improved degree of integration.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a semiconductor device includes a lower substrate, a memory cell structure including a wordline on the lower substrate, a bitline disposed on the lower substrate and intersecting the wordline, and a cell capacitor connected to the lower substrate, an upper substrate having a back side adjacent to the lower substrate and a front side opposite to the back side, a circuit element disposed on the front side of the upper substrate and overlapping the memory cell structure in a vertical direction, and a through via penetrating the upper substrate and electrically connecting the memory cell structure and the circuit element with each other.

According to an aspect of the present disclosure, a semiconductor device includes a lower substrate including a cell area and an extension area adjacent to the cell area, a memory cell structure including a wordline disposed on the cell area and extending from the cell area in a first direction beyond an outer boundary of the cell area into the extension area, an end portion of the wordline being disposed on the extension area, a bitline disposed on the cell area and extending from the cell area in a second direction beyond the outer boundary of the cell area into the extension area, an end portion of the bitline being disposed on the extension area, and a cell capacitor disposed on the cell area, a lower insulating structure disposed on the lower substrate and covering the memory cell structure, a lower wiring structure disposed in the lower insulating structure and connected to the end portion of the wordline and the end portion of the bitline on the extension area, a bonding insulating film on the lower insulating structure, an upper substrate disposed on the bonding insulating film and having a back side adjacent to the lower substrate and a front side opposite to the back side, a plurality of circuit elements on the front side of the upper substrate, an upper insulating structure disposed on the upper substrate and covering the plurality of circuit elements, an upper wiring structure disposed in the upper insulating structure and connected to the plurality of circuit elements, and a plurality of through vias penetrating the upper substrate and the bonding insulating film and electrically connecting the lower wiring structure and the upper wiring structure with each other.

According to an aspect of the present disclosure, a semiconductor device includes a lower substrate including a gate trench, wherein the gate trench extends in a first direction, a memory cell structure including a wordline disposed in the gate trench and extending in the first direction in the gate trench, a bitline disposed on the lower substrate and extending in a second direction intersecting the first direction, and a cell capacitor disposed on the bitline and connected to the lower substrate, an upper substrate having a back side adjacent to the lower substrate, and a front side opposite to the back side, the upper substrate including a sense amplifier area and a sub-wordline driver area, a first circuit element disposed on the front side of the sense amplifier area, a second circuit element disposed on the front side of the sub-wordline driver area, a first through via penetrating the upper substrate and electrically connecting the bitline and the first circuit element with each other, and a second through via penetrating the upper substrate and electrically connecting the wordline and the second circuit element with each other. At least one of the first circuit element and the second circuit element overlaps the memory cell structure in a vertical direction.

According to a method of fabricating a semiconductor device includes forming a lower bonding structure including a lower substrate and a memory cell structure on the lower substrate, wherein the memory cell structure includes a wordline on the lower substrate, a bitline intersecting the wordline, and a cell capacitor connected to the lower substrate, forming an upper bonding structure including an upper substrate and a circuit element on the upper substrate, wherein the upper substrate has a front side on which the circuit element is disposed, and a back side opposite to the front side, bonding the upper bonding structure to the lower bonding structure such that the back side of the upper substrate is adjacent to the lower substrate, and forming a through via penetrating the upper substrate and electrically connecting the memory cell structure and the circuit element with each other.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout view of a semiconductor device according to some embodiments of the present disclosure.

FIG. 2 is an enlarged layout view of a region R1 of FIG. 1.

FIG. 3 is an enlarged layout view of a region R2 of FIG. 2.

FIG. 4 is a cross-sectional view taken along lines A1-A1 and B1-B1 of FIG. 3.

FIG. 5 is an enlarged cross-sectional view of a region R3 of FIG. 4.

FIG. 6 is a cross-sectional view of a first peripheral area of FIG. 1.

FIGS. 7A through 7E are enlarged cross-sectional views of regions R3 (of FIG. 4) of semiconductor devices according to some embodiments of the present disclosure.

FIG. 8 is an enlarged layout view of a region R2 (of FIG. 2) of a semiconductor device according to some embodiments of the present disclosure.

FIG. 9 is a cross-sectional view taken along lines A2-A2 and B2-B2 of FIG. 8.

FIG. 10 is an enlarged layout view of a region R2 (of FIG. 2) of a semiconductor device according to some embodiments of the present disclosure.

FIG. 11 is a cross-sectional view taken along lines A3-A3 and B3-B3 of FIG. 10.

FIGS. 12 through 16 are layout views of semiconductor devices according to some embodiments of the present disclosure.

FIG. 17 is a layout view of a memory cell structure of a semiconductor device according to some embodiments of the present disclosure.

FIG. 18 is a cross-sectional view taken along line C-C of FIG. 17.

FIG. 19 is a cross-sectional view taken along line D-D of FIG. 17.

FIGS. 20 through 29 are cross-sectional views illustrating a method of fabricating a semiconductor device according to some embodiments of the present disclosure.

### DETAILED DESCRIPTION

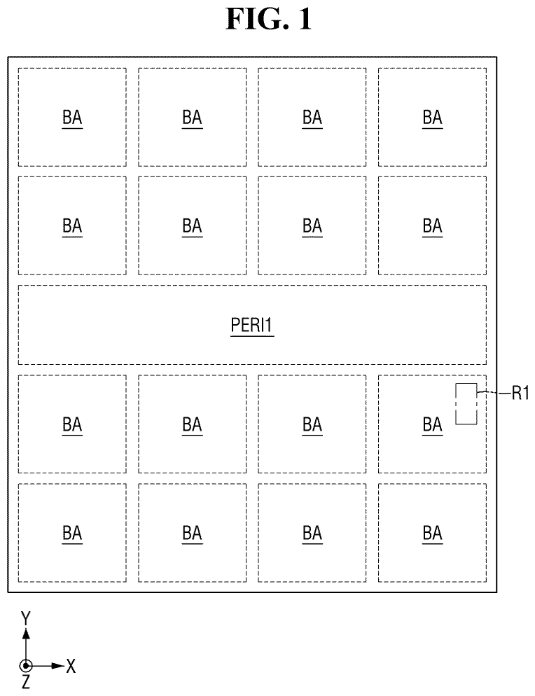

Semiconductor devices according to some embodiments of the present disclosure will be described with reference to FIGS. 1 through 19.

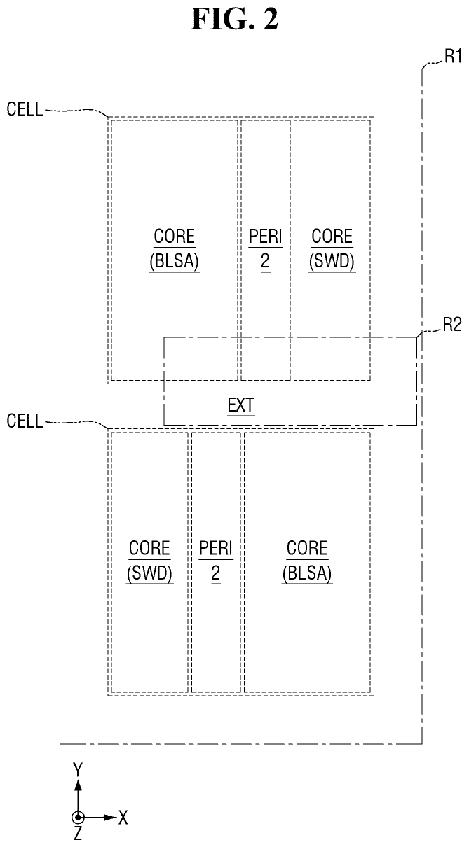

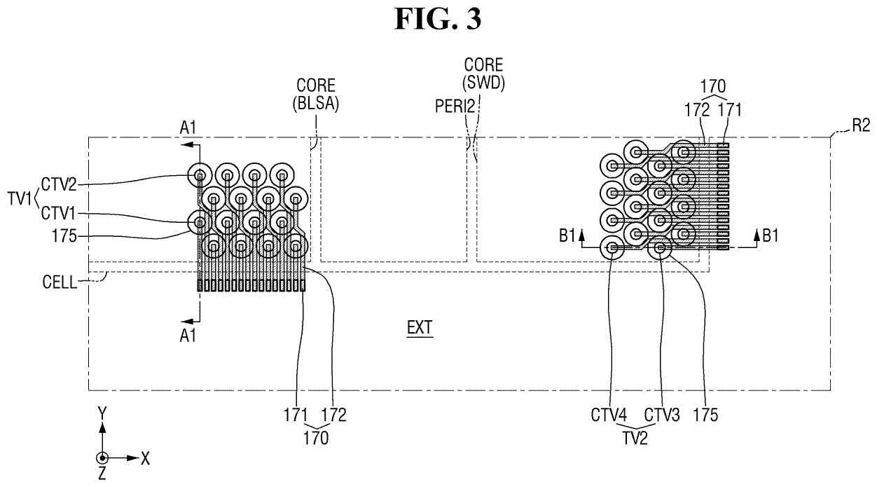

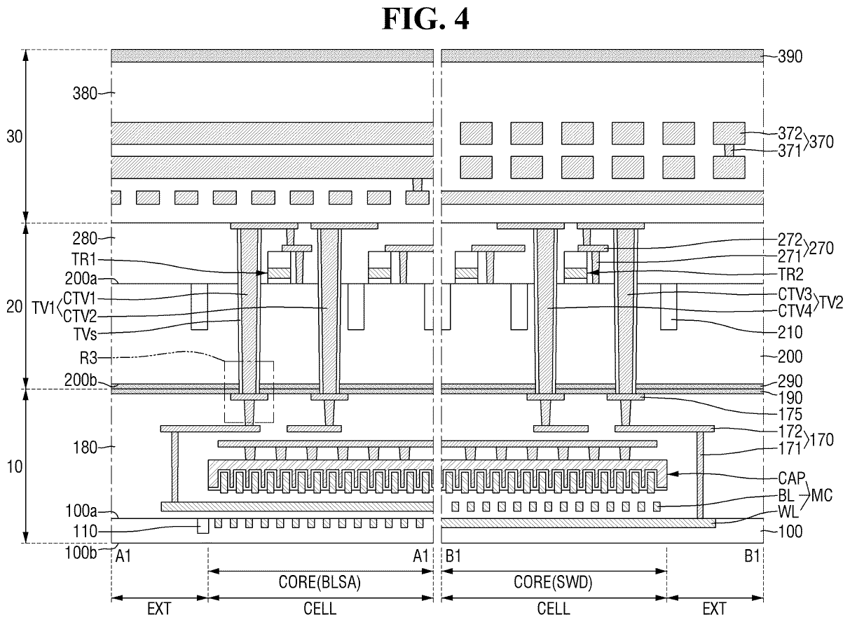

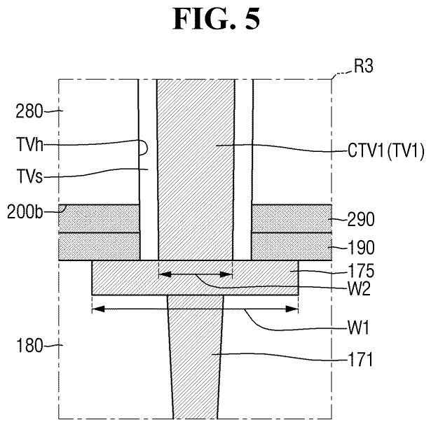

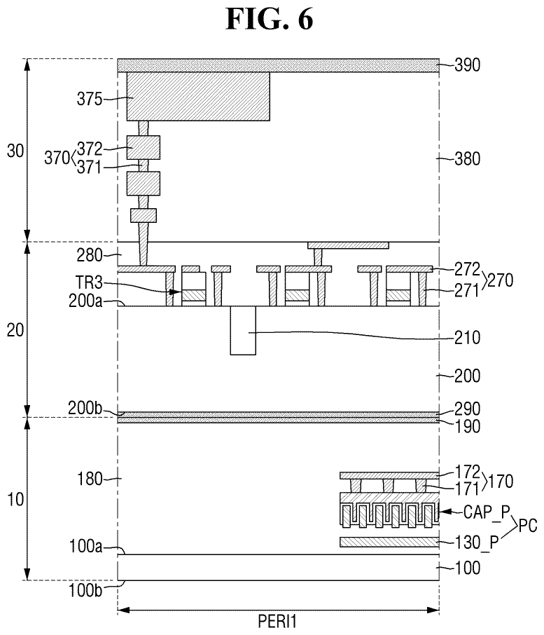

FIG. 1 is a layout view of a semiconductor device according to some embodiments of the present disclosure. FIG. 2 is an enlarged layout view of a region R1 of FIG. 1. FIG. 3 is an enlarged layout view of a region R2 of FIG. 2. FIG. 4 is a cross-sectional view taken along lines A1-A1 and n1-n1 of FIG. 3. FIG. 5 is an enlarged cross-sectional view of a region R3 of FIG. 4. FIG. 6 is a cross-sectional view of a first peripheral area of FIG. 1.

Referring to FIGS. 1 and 2, the semiconductor device according to some embodiments of the present disclosure may include a plurality of bank areas BA and a first peripheral region PERI1.

The first peripheral area PERI1 may be disposed between the bank areas BA. Peripheral circuits for the input and output of data and commands or the input of power/ground may be disposed on the first peripheral area PERI1.

Each of the bank areas BA may include cell areas CELL and an extension area EXT. A memory cell structure MC that will be described later may be disposed on the cell areas CELL. The extension area EXT may be adjacent to the cell areas CELL. For example, the extension area EXT may surround the cell areas CELL.

Each of the bank areas BA may include core areas CORE and second peripheral areas PERI2. The second peripheral areas PERI2 may be disposed between the core areas CORE. In some embodiments, the core areas CORE may include sense amplifier areas BLSA and sub-wordline driver areas SWD. Sense amplifiers may be disposed on the sense amplifier areas BLSA, and sub-wordline drivers may be disposed in the sub-wordline driver areas SWD. At least some of the core areas CORE and/or at least some of the second peripheral areas PERI2 may overlap one of the cell areas CELL, and this will be described later with reference to FIGS. 3 through 5.

Referring to FIGS. 1 through 6, the semiconductor device according to some embodiments of the present disclosure may include a lower bonding structure 10, an upper bonding structure 20, and a connection structure 30.

The lower bonding structure 10 may include a lower substrate 100, lower device isolation patterns 110, the memory cell structure MC, a power capacitor structure PC, a lower insulating structure 180, and a lower wiring structure 170.

The lower substrate 100 may be in the shape of a plate extending along a plane including first and second directions X and Y. The first and second directions X and Y may intersect each other. For example, the first and second directions X and Y may be horizontal directions that are orthogonal to each other. The lower substrate 100 may have a structure in which a base substrate and an epitaxial layer are stacked, but the present disclosure is not limited thereto. The lower substrate 100 may be a silicon (Si) substrate, a gallium arsenide (GaAs) substrate, a silicon-germanium (SiGe) substrate, or a semiconductor-on-insulator (SOI) substrate. The lower substrate 100 will be hereinafter described as being, for example, a Si substrate.

The lower substrate 100 may have first and second surfaces 100a and 100b, which are opposite to each other. The first surface 100a may also be referred to as the front side of the lower substrate 100, and the second surface 100b may also be referred to as the back side of the lower substrate 100. The lower substrate 100 may include cell areas CELL and an extension area EXT.

The lower device isolation patterns 110 may be formed in the lower substrate 100. The lower device isolation patterns 110 may include or may be formed of an insulating material, for example, at least one of silicon oxide, silicon nitride, silicon oxynitride, silicon oxycarbonitride, and a combination thereof, but the present disclosure is not limited thereto. The lower device isolation patterns 110 may be single films including only one insulating material or may be multifilms including a combination of various types of insulating materials.

The memory cell structure MC may be disposed on the first surface 100a of the lower substrate 100. The memory cell structure MC may be disposed on the cell areas CELL. In some embodiments, a semiconductor device including the memory cell structure MC may form a dynamic random-access memory (DRAM). For example, the memory cell structure MC may include a plurality of wordlines WL, a plurality of bitlines BL, and a cell capacitor CAP.

The wordlines WL may be disposed on the lower substrate 100. The wordlines WL may extend in parallel to one another in the first direction X. For example, the wordlines WL may all extend in the first direction X and may be arranged along the second direction Y. The wordlines WL may extend even into the extension area EXT, beyond the cell areas CELL. For example, the wordlines WL may extend in the first direction X over the cell areas CELL, and the ends of the wordlines WL may be disposed on the extension area EXT. In some embodiments, the wordlines WL may be buried in the lower substrate 100.

The bitlines BL may be disposed on the lower substrate 100. The bitlines BL may extend in parallel to one another in the second direction Y. For example, the bitlines BL may all extend in the second direction Y and may be arranged along the first direction X. The bitlines BL may extend even into the extension area EXT, beyond the cell areas CELL. For example, the bitlines BL may extend in the second direction Y over the cell areas CELL, and the ends of the bitlines BL may be disposed on the extension area EXT. In some embodiments, the bitlines BL may be formed on the first surface 100a of the lower substrate 100.

The cell capacitor CAP may be disposed on the lower substrate 100. The cell capacitor CAP may be physically and electrically connected to the lower substrate 100. The cell capacitor CAP may be controlled by the wordlines WL and the bitlines BL to store data. In some embodiments, the cell capacitor CAP may be disposed on the bitlines BL. For example, the bitlines BL may be interposed between the cell capacitor CAP and the wordlines WL.

The power capacitor structure PC may be disposed on the first surface 100a of the lower substrate 100. The power capacitor structure PC may be disposed on the first peripheral area PERI1. The power capacitor structure PC may be disposed on the same level as the memory cell structure MC. When two elements are disposed on the same level, it may be understood that the two elements are at the same height in a vertical direction, for example, in a third direction Z, which intersects the first and second directions X and Y. The power capacitor structure PC may be provided as a capacitor for the input of power/ground.

The power capacitor structure PC may include power capacitor conductive lines 130_P and a power capacitor CAP_P. The power capacitor conductive lines 130_P may be disposed on the same level as the bitlines BL. The power capacitor CAP_P may be disposed on the same level as the cell capacitor CAP. The power capacitor conductive lines 130_P and the power capacitor CAP_P may be similar to the bitlines BL and the cell capacitor CAP, respectively, and thus, detailed descriptions thereof will be omitted.

The lower insulating structure 180 may be disposed on the first surface 100a of the lower substrate 100. The lower insulating structure 180 may cover the memory cell structure MC and the power capacitor structure PC. The lower insulating structure 180 is illustrated as being a single film, but the present disclosure is not limited thereto. The lower insulating structure 180 may be a multilayer insulating film including a plurality of insulating films. The lower insulating structure 180 may include or may be formed of at least one of, for example, silicon oxide, silicon oxynitride, and a low-k dielectric material having a smaller dielectric constant than silicon oxide, but the present disclosure is not limited thereto.

The lower wiring structure 170 may be disposed in the lower insulating structure 180. The lower wiring structure 170 may include a plurality of lower via patterns 171 and a plurality of lower wiring patterns 172. The lower via patterns 171 may be connected to the lower wiring patterns 172, which are multilayered. In some embodiments, each of the lower via patterns 171 may contact a corresponding one of the lower wiring patterns 172. The lower via patterns 171 and the lower wiring patterns 172 may be insulated from one another by the lower insulating structure 180. The number of levels, the number, and the layout of lower via patterns 171 and the number of levels, the number, and the layout of lower wiring patterns 172 are not particularly limited.

In some embodiments, as an etching process for forming the lower via patterns 171 is performed on the first surface 100a of the lower substrate 100, the width of the lower via patterns 171 may gradually decrease in a direction toward the first surface 100a of the lower substrate 100.

The lower wiring structure 170 may be electrically connected to the memory cell structure MC and the power capacitor structure PC. For example, as illustrated in FIG. 4, some of the lower via patterns 171 may be connected to the wordlines WL on the extension area EXT, and some of the lower via patterns 171 may be connected to the bitlines BL on the extension area EXT. In some embodiments, the lower via patterns 171 may be disposed on the extension area EXT and the first peripheral area PERI1. Some of the lower via patterns 171 may connect some of the lower wiring patterns 172 to the wordlines WL on the extension area EXT. Some of the lower via patterns 171 may connect some of the lower wiring patterns 172 to the bitlines BL on the extension area EXT. As illustrated in FIG. 6, some of the lower via patterns 171 may be connected to the power capacitor CAP_P on the first peripheral area PERI1.

The upper bonding structure 20 may include an upper substrate 200, upper device isolation patterns 210, first circuit elements TR1, second circuit elements TR2, third circuit elements TR3, an upper insulating structure 280, an upper wiring structure 270, and through vias TV1 and TV2. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The upper substrate 200 may be in the shape of a plate extending along the plane including first and second directions X and Y. The upper substrate 200 may have a structure in which a base substrate and an epitaxial layer are stacked, but the present disclosure is not limited thereto. The upper substrate 200 may be a Si substrate, a GaAs substrate, a SiGe substrate, or an SOI substrate. The upper substrate 200 will be hereinafter described as being, for example, a Si substrate.

The upper substrate 200 may have third and fourth surfaces 200a and 200b, which are opposite to each other. The third surface 200a may also be referred to as the front side of the upper substrate 200, and the fourth surface 200b may also be referred to as the back side of the upper substrate 200. The upper substrate 200 may include core areas CORE, second peripheral areas PERI2, and an extension area EXT.

The upper device isolation patterns 210 may be formed in the upper substrate 200. The upper device isolation patterns 210 may include or may be formed of an insulating material, for example, at least one of silicon oxide, silicon nitride, silicon oxynitride, silicon oxycarbonitride, and a combination thereof, but the present disclosure is not limited thereto. The upper device isolation patterns 210 may be single films including only one insulating material or may be multifilms including a combination of various types of insulating materials.

The first circuit elements TR1, the second circuit elements TR2, and the third circuit elements TR3 may be disposed on the third surface 200a of the upper substrate 200. The first circuit elements TR1 and the second circuit elements TR2 may be disposed at the core areas CORE and may form circuitry at the core areas CORE. The third circuit elements TR3 may be disposed on the first peripheral area PERI1 and may form circuitry on the first peripheral area PERI1.

In some embodiments, the core areas CORE may include the sense amplifier areas BLSA and the sub-wordline driver areas SWD. The first circuit elements TR1 may be disposed on the sense amplifier areas BLSA, and the second circuit elements TR2 may be disposed on the sub-wordline driver areas SWD. In some embodiments, the first circuit elements TR1 may form sense amplifiers, which are electrically connected to the bitlines BL, and the second circuit elements TR2 may form sub-wordline drivers, which are electrically connected to the wordlines WL.

At least some of the core areas CORE and/or at least some of the second peripheral areas PERI2 may overlap one another. When two elements overlap each other, it may be understood that the two elements overlap each other in the vertical direction (e.g., in the third direction Z). For example, as illustrated in FIG. 3, a sense amplifier area BLSA, a second peripheral area PERI2, and a sub-wordline driver area SWD may overlap a cell area CELL. As illustrated in FIG. 4, the first circuit elements TR1 and the second circuit elements TR2 may overlap the memory cell structure MC. In some embodiments, as illustrated in FIG. 6, as at least some of the third circuit elements TR3 may overlap the power capacitor structure PC.

The upper insulating structure 280 may be disposed on the third surface 200a of the upper substrate 200. The upper insulating structure 280 may cover the first circuit elements TR1, the second circuit elements TR2, and the third circuit elements TR3. The upper insulating structure 280 is illustrated as being a single film, but the present disclosure is not limited thereto. In some embodiments, the upper insulating structure 280 may be a multilayer insulating film including a plurality of insulating films. The upper insulating structure 280 may include or may be formed of at least one, for example, silicon oxide, silicon oxynitride, and a low-k dielectric material having a smaller dielectric constant than silicon oxide, but the present disclosure is not limited thereto.

The upper wiring structure 270 may be disposed in the upper insulating structure 280. The upper wiring structure 270 may include a plurality of upper via patterns 271 and a plurality of upper wiring patterns 272. The upper via patterns 271 may be connected to the upper wiring patterns 272, which are formed in a multi-level structure. In some embodiments, each of the upper via patterns 271 may contact a corresponding one of the upper wiring patterns 272. The upper via patterns 271 and the upper wiring patterns 272 may be insulated from one another by the upper insulating structure 280. The number of levels, the number, and the layout of upper via patterns 271 and the number of levels, the number, and the layout of upper wiring patterns 272 are not particularly limited.

In some embodiments, as an etching process for forming the upper via patterns 271 is performed on the third surface 200a of the upper substrate 200, the width of the upper via patterns 271 may gradually decrease in a direction toward the third surface 200a of the upper substrate 200.

The upper wiring structure 270 may be electrically connected to the first circuit elements TR1, the second circuit elements TR2, and the third circuit elements TR3. For example, as illustrated in FIG. 4, some of the upper via patterns 271 that are disposed on the sense amplifier areas BLSA may be connected to the first circuit elements TR1 on the sense amplifier areas BLSA, and some of the upper via patterns 271 that are disposed on the sub-wordline driver areas SWD may be connected to the second circuit elements TR2 on the sub-wordline driver areas SWD. For example, as illustrated in FIG. 6, some of the upper via patterns 271 that are disposed on the first peripheral area PERI1 may be connected to the third circuit elements TR3 on the first peripheral area PERI1.

The upper bonding structure 20 may be stacked on the lower bonding structure 10. The upper bonding structure 20 may be bonded onto the lower bonding structure 10 in a face-to-back (F2B) bonding method. The back side (i.e., the fourth surface 200b) of the upper substrate 200 may face the front side (i.e., the first surface 100a) of the lower substrate 100. In some embodiments, the fourth surface 200b of the upper substrate 200 may be adjacent to the first surface 100a of the lower substrate 100.

In some embodiments, the lower bonding structure 10 and the upper bonding structure 20 may be bonded together in a dielectric bonding method. For example, the upper bonding structure 20 may include a first bonding insulating film 190 on the lower insulating structure 180, and the lower bonding structure 10 may include a second bonding insulating film 290 on the fourth surface 200b of the lower substrate 100. As the first and second bonding insulating films 190 and 290 are bonded together, the upper bonding structure 20 may be stacked onto the lower bonding structure 10. For example, the first and second bonding insulating films 190 and 290 may include or may be oxide films (e.g., SiO₂ films), in which case, the dielectric bonding method may be an oxide-to-oxide bonding method. However, the present disclosure is not limited to this example. In some embodiments, the first and second bonding insulating films 190 and 290 may include or may be carbonitride films (e.g., SiCN films) or oxycarbonitride films (e.g., SiCON films).

The through vias TV1 and TV2 may extend in the third direction Z and may penetrate the upper substrate 200. For example, as illustrated in FIG. 5, through via holes TVh may be formed to sequentially penetrate the upper insulating structure 280, the upper substrate 200, the second bonding insulating film 290, and the first bonding insulating film 190. The through vias TV1 and TV2 may be formed in the through via holes TVh to sequentially penetrate the upper insulating structure 280, the upper substrate 200, the second bonding insulating film 190, and the first bonding insulating film 190.

The through vias TV1 and TV2 may electrically connect the lower wiring structure 170 and the upper wiring structure 270 with each other. For example, the lower bonding structure 10 may include a plurality of via pads 175, which are exposed from the lower insulating structure 180. The through vias TV1 and TV2 may be connected to the respective via pads 175. For example, the through vias TV1 and TV2 may contact the respective via pads 175. The via pads 175 may be electrically connected to the lower wiring structure 170 through the lower via patterns 171. In some embodiments, the via pads 175 may be uppermost lower wiring patterns 172.

The circuit elements (e.g., the first circuit elements TR1, the second circuit elements TR2, and the third circuit elements TR3) of the upper bonding structure 20 may be electrically connected to the memory cell structure MC and/or the power capacitor structure PC of the lower bonding structure 10. For example, the through vias TV1 and TV2 may include first through vias TV1 and second through vias TV2. The first through vias TV1 may electrically connect the first circuit elements TR1 and the bitlines BL with each other. The second through vias TV2 may electrically connect the second circuit elements TR2 and the wordlines WL with each other.

The through vias TV1 and TV2 may include or may be formed of a conductive material, for example, at least one of aluminum (Al), copper (Cu), tungsten (W), molybdenum (Mo), cobalt (Co), ruthenium (Ru), and an alloy thereof, but the present disclosure is not limited thereto.

FIG. 3 illustrates the via pads 175 and the through vias TV1 and TV2 have a circular shape when viewed in a plan view, but the present disclosure is not limited thereto. The via pads 175 and the through vias TV1 and TV2 may have various other shapes such as a rectangular or hexagonal shape when viewed in a plan view.

In some embodiments, the through vias TV1 and TV2 may be arranged in a zigzag or honeycomb fashion. For example, as illustrated in FIG. 3, the through vias TV1 and TV2 may be arranged in a staggered manner in the first and second directions X and Y.

In some embodiments, through spacers TVs may be interposed between the upper substrate 200 and the through vias TV1 and TV2. The through spacers TVs may surround the through vias TV1 and TV2. For example, the through spacers TVs may extend along the sides of the through via holes TVh, and the through vias TV1 and TV2 may fill parts of the through via holes TVh that are not filled with the through spacers TVs. The through vias TV1 and TV2 may be electrically isolated from the upper substrate 200 by the through spacers TVs. The through spacers TVs may include or may be formed of an insulating material, for example, at least one of silicon oxide, silicon nitride, silicon oxynitride, silicon oxycarbonitride, and a combination thereof, but the present disclosure is not limited thereto.

In some embodiments, as an etching process for forming the through via holes TVh is performed on the third surface 200a of the upper substrate 200, the width of the through vias TV1 and TV2 may gradually decrease in a direction from the upper substrate 200 to the lower substrate 100 (i.e., in the opposite direction of the third direction Z).

In some embodiments, at least some of the through vias TV1 and TV2 may overlap one of the cell areas CELL. For example, as illustrated in FIG. 3, the first through vias TV1 may include first cell area through vias CTV1 and second cell area through vias CTV2, and the second through vias TV2 may include third cell area through vias CTV3 and fourth cell area through vias CTV4. The first cell area through vias CTV1 and the second cell area through vias CTV2 may be disposed in a sense amplifier area BLSA, which overlaps a cell area CELL. The third cell area through vias CTV3 and the fourth cell area through vias CTV4 may be disposed in a sub-wordline driver area SWD, which overlaps the cell area CELL.

FIG. 3 illustrates that all the first through vias TV1 and all the second through vias TV2 overlap the cell area CELL, but the present disclosure is not limited thereto. In some embodiments, some of the first through vias TV1 and some of the second through vias TV2 may overlap an extension area EXT.

In some embodiments, lower via patterns 171 connected to the first through vias TV1 may be arranged in a row in the first direction X. Lower wiring patterns 172 connected to the first through vias TV1 may extend in the second direction Y and may thus be connected to the respective lower via patterns 171. In this manner, the first through vias STV1 may be electrically connected to the lower wiring structure 170.

In some embodiments, lower via patterns 171 connected to the second through vias TV2 may be arranged in a row in the second direction Y. Lower wiring patterns 172 connected to the second through vias TV2 may extend in the first direction X and may thus be connected to the respective lower via patterns 171. In this manner, the second through vias STV2 may be electrically connected to the lower wiring structure 170.

In some embodiments, referring to FIG. 5, a width W1 of the via pads 175 may be greater than a width W2 of the through vias TV1 and TV2. For example, the through via holes TVh may expose parts of the top surfaces of the via pads 175.

In some embodiments, the via pads 175 may be exposed from the top surface of the lower insulating structure 180. The first bonding insulating film 190 may cover parts of the top surfaces of the via pads 175 that are not exposed by the through via holes TVh.

The connection structure 30 may be stacked on the upper bonding structure 20. The connection structure 30 may include a connection insulating structure 380, a connection wiring structure 370, and a passivation film 390.

The connection insulating structure 380 may be disposed on the upper insulating structure 280. The connection insulating structure 380 may cover the upper insulating structure 280 and/or the upper wiring structure 270. The connection insulating structure 380 is illustrated as being a single film, but the present disclosure is not limited thereto. In some embodiments, the connection insulating structure 380 may be a multilayer insulating film including a plurality of insulating films. The connection insulating structure 380 may include or may be formed of at least one of, for example, silicon oxide, silicon oxynitride, and a low-k dielectric material having a smaller dielectric constant than silicon oxide, but the present disclosure is not limited thereto.

The connection wiring structure 370 may be disposed in the connection insulating structure 380. The connection wiring structure 370 may include a plurality of connection via patterns 371 and a plurality of connection wiring patterns 372. The connection via patterns 371 may connect the connection wiring patterns 372, which are formed in a multi-level structure. The connection via patterns 371 and the connection wiring patterns 372 may be insulated from one another by the connection insulating structure 380. The number of levels, the number, and the layout of connection via patterns 371 and the number of levels, the number, and the layout of connection wiring patterns 372 are not particularly limited.

The connection wiring structure 370 may be electrically connected to the lower bonding structure 10 and/or the upper bonding structure 20. For example, as illustrated in FIG. 6, some of the connection via patterns 371 may be connected to the upper wiring structure 270 on the first peripheral area PERI1.

The passivation film 390 may be disposed on the connection insulating structure 380. The passivation film 390 may cover the top surface of the connection insulating structure 380. The passivation film 390 may include or may be formed of an insulating material, for example, at least one of silicon oxide, silicon nitride, silicon oxynitride, silicon oxycarbonitride, and a combination thereof, but the present disclosure is not limited thereto. The passivation film 390 may include or may be formed of the same insulating material as, or a different insulating material from, the connection insulating structure 380. For example, the connection insulating structure 380 may include or may be formed of a silicon oxide film, and the passivation film 390 may include or may be a silicon nitride film.

The semiconductor device according to some embodiments of the present disclosure may be electrically connected to an external device (not illustrated) via the connection structure 30. For example, the connection structure 30 may include terminals 375, which are exposed from the connection insulating structure 380 and/or from the passivation film 390. The external device may be connected to the terminals 375. The terminals 375 may be electrically connected to the connection wiring structure 370 via the connection via patterns 371. In some embodiments, the terminals 375 may be uppermost connection wiring patterns 372.

As described above, as the core areas CORE are stacked on the cell areas CELL, and the cell areas CELL and the core areas CORE are electrically connected with each other via the through vias TV1 and TV2, a core-on-cell structure can be provided. Accordingly, when viewed in a plan view, the area occupied by the core areas CORE can be reduced, and thus, the degree of integration of the semiconductor device according to some embodiments of the present disclosure can be improved. The size of circuit elements forming each of the core areas CORE (e.g., the size of transistors forming a sense amplifier and/or a sub-wordline driver) can be increased. As a result, the manufacturing cost of circuit elements can be reduced, and the electrical characteristics of circuit elements can be improved.

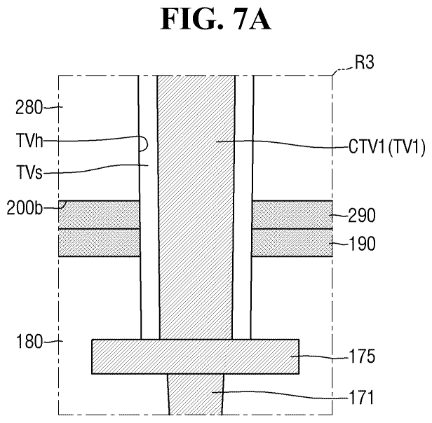

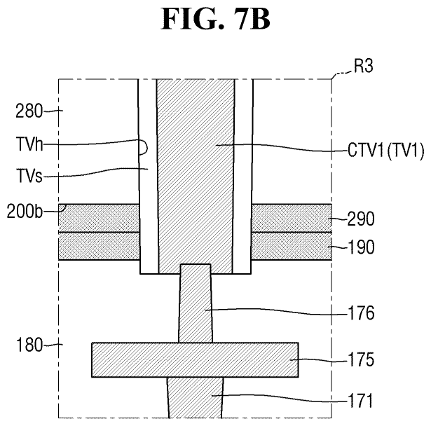

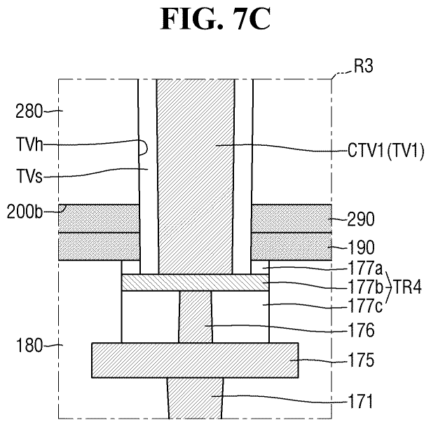

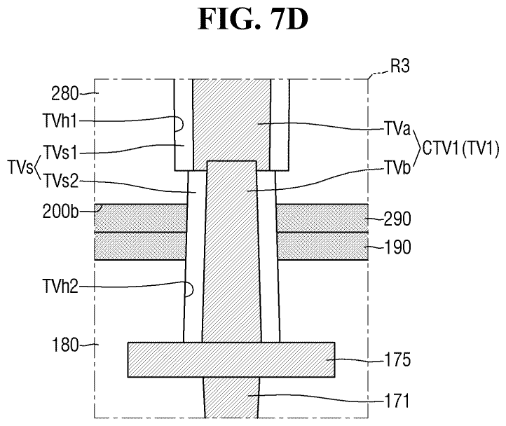

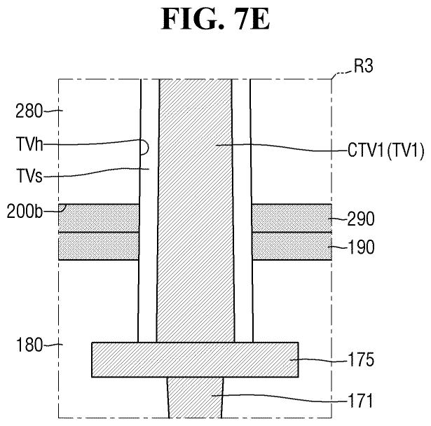

FIGS. 7A through 7E are enlarged cross-sectional views of regions R3 (of FIG. 4) of semiconductor devices according to some embodiments of the present disclosure. For convenience, the embodiments of FIGS. 7A through 7E will be hereinafter described, focusing mainly on the differences with the embodiment of FIGS. 1 through 6.

Referring to FIGS. 4 and 7A, via pads 175 may be spaced apart from a first bonding insulating film 190.

For example, the top surface of the via pads 175 may be positioned lower than the uppermost surface of a lower insulating structure 180. Through via holes TVh may penetrate a part of the lower insulating structure 180 to expose at least parts of the top surfaces of the via pads 175. Through vias TV1 and TV2 may be formed in the through via holes TVh and may thus be connected to the via pads 175. Accordingly, the bottom surfaces of the through vias TV1 and TV2 may be positioned lower than the bottom surface of the first bonding insulating film 190.

Referring to FIGS. 4 and 7B, the semiconductor device according to some embodiments of the present disclosure may further include via contacts 176.

The via contacts 176 may connect via pads 175 and through vias TV1 and TV2 with each other. For example, upper ends of the via contacts 176 may contact the through vias TV1 and TV2, and lower ends of the via contacts 176 may contact the via pads 175. In some embodiments, the width of the via contacts 176 may gradually decrease in a direction from a lower substrate 100 to an upper substrate 200 (i.e., in a third direction Z). In some embodiments, the via contacts 176 may penetrate the bottom surfaces of the through vias TV1 and TV2. For example, lower parts of the through vias TV1 and TV2 may surround upper parts of the via contacts 176.

Referring to FIGS. 4 and 7C, the semiconductor device according to some embodiments of the present disclosure may further include fourth circuit elements TR4.

The fourth circuit elements TR4 may be transistors. For example, the fourth circuit elements TR4 may include gate dielectric films 177a, gate electrodes 177b, and gate capping films 177c, which are sequentially stacked on the bottom surface of a first bonding insulating film 190.

Through vias TV1 and TV2 may penetrate the gate dielectric films 177a to be connected to the gate electrodes 177b. Via contacts 176 may penetrate the gate capping films 177c to be connected to the gate electrodes 177b. Accordingly, the through vias TV1 and TV2 may be electrically connected to via pads 175.

Referring to FIGS. 4 and 7D, through vias TV1 and TV2 may include first vias TVa and second vias TVb.

The first vias Tva may be connected to an upper wiring structure 270. The second vias TVb may connect the first vias Tva and via pads 175 with each other. For example, first through via holes TVh1, which penetrate an upper insulating structure 280 to extend into an upper substrate 200, may be formed. Second through via holes TVh2, which extend from the via pads 175 to be connected to the first through via holes TVh1 through first and second bonding insulating films 190 and 290, may be formed. The first vias TVa may be formed in the first through via holes TVh1, and the second vias TVb may be formed in the second through via holes TVh2. Accordingly, the first vias TVa and the second vias TVb may be electrically connected to one another. In some embodiments, the first vias TVa may contact the second vias TVb.

The first vias TVa and the second vias TVb may include or may be formed of the same conductive material or different conductive materials.

In some embodiments, the width of the first vias TVa may gradually decrease in a direction from the upper substrate 200 to a lower substrate 100 (i.e., in the opposite direction of a third direction Z). The width of the second vias TVb may gradually decrease in a direction from the lower substrate 100 to the upper substrate 200 (i.e., in the third direction Z).

In some embodiments, the second vias TVb may penetrate the bottom surfaces of the first vias TVa. For example, lower parts of the first vias TVa may surround upper parts of the second vias TVb. In some embodiments, upper parts of the second vias TVb may partially buried in the lower parts of the first vias TVa, which may increase contact areas between the first and second vias TVa and TVb thereby lowering contact resistance.

In some embodiments, through spacers TVs may include first spacers TVs1 and second spacers TVs2. The first spacers TVs1 may surround the first vias TVa, and the second spacers TVs2 may surround the second vias TVb. The first spacers TVs1 and the second spacers TVs2 may include or may be formed of the same insulating material or different insulating materials.

Referring to FIGS. 4 and 7E, as an etching process for forming a through via hole TVh is performed on a fourth surface 200b of an upper substrate 200, the width of through vias TV1 and TV2 may gradually decrease in a direction from a lower substrate 100 to the upper substrate 200 (i.e., in a third direction Z).

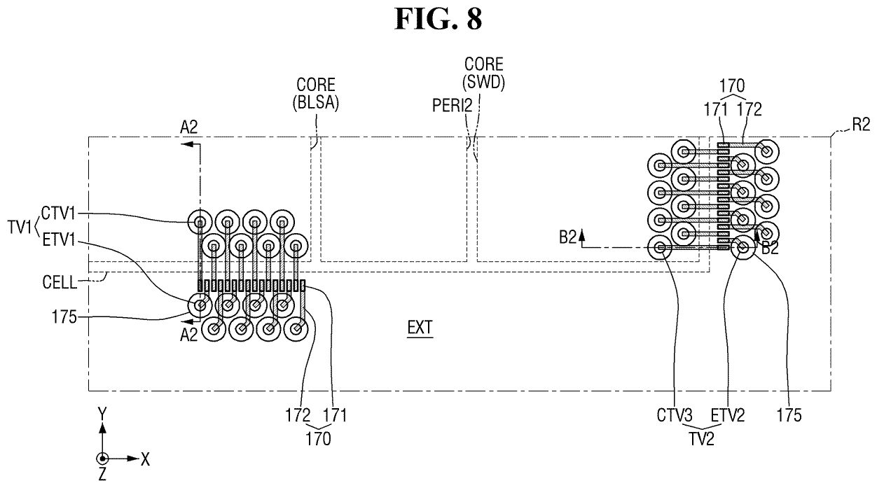

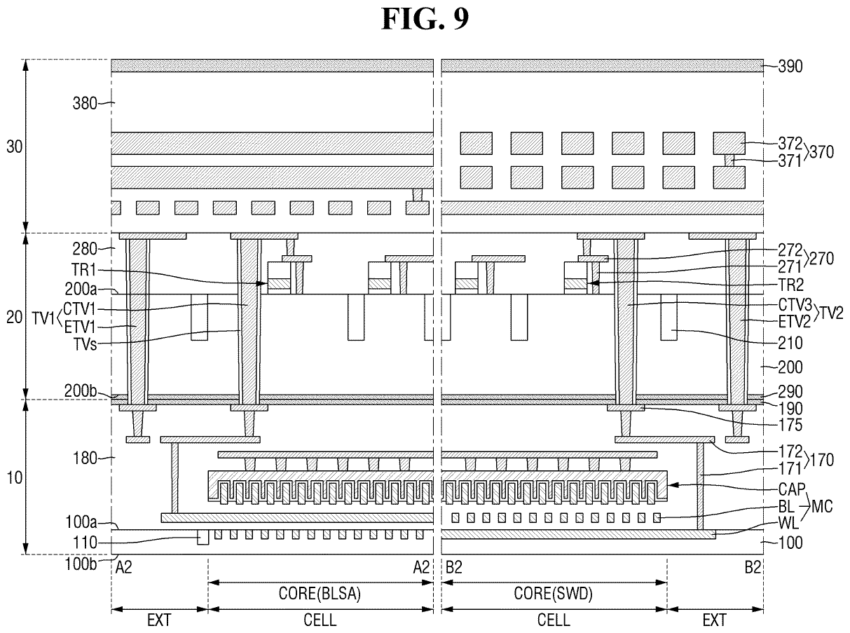

FIG. 8 is an enlarged layout view of a region R2 (of FIG. 2) of a semiconductor device according to some embodiments of the present disclosure. FIG. 9 is a cross-sectional view taken along lines A2-A2 and B2-B2 of FIG. 8. For convenience, the embodiment of FIGS. 8 and 9 will be hereinafter described, focusing mainly on the differences with the embodiments of FIGS. 1 through 7E.

Referring to FIGS. 1, 2, 8, and 9, some of through vias TV1 and TV2 may overlap a cell area CELL, and some of the through vias TV1 and TV2 may overlap an extension area EXT.

For example, first through vias TV1 may include first cell area through vias CTV1 and first extension area through vias ETV1, and second through vias TV2 may include third cell area through vias CTV3 and second extension area through vias ETV2. The first cell area through vias CTV1 may be disposed in a sense amplifier area BLSA, which overlaps the cell area CELL, and the first extension area through vias ETV1 may overlap a part of the extension area EXT adjacent to the sense amplifier area BLSA. The third cell area through vias CTV3 may be disposed in a sub-wordline driver area SWD, which overlaps the cell area CELL, and the second extension area through vias ETV2 may overlap a part of the extension area EXT adjacent to the sub-wordline driver area SWD.

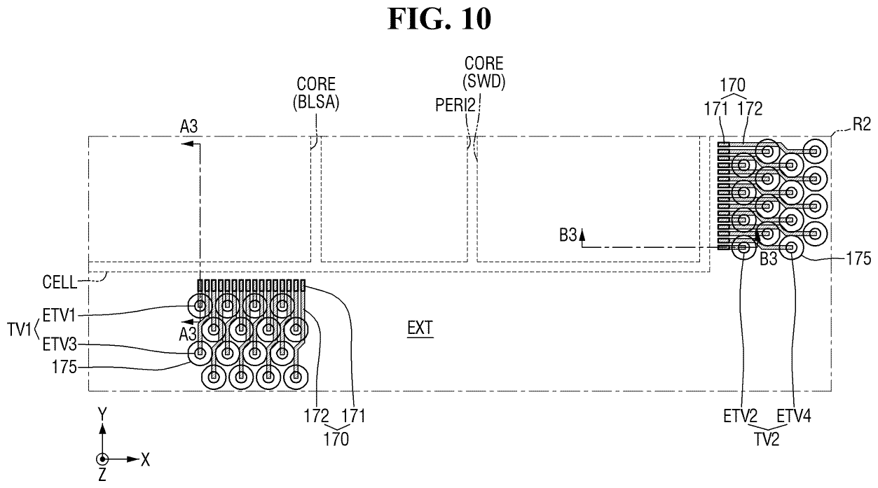

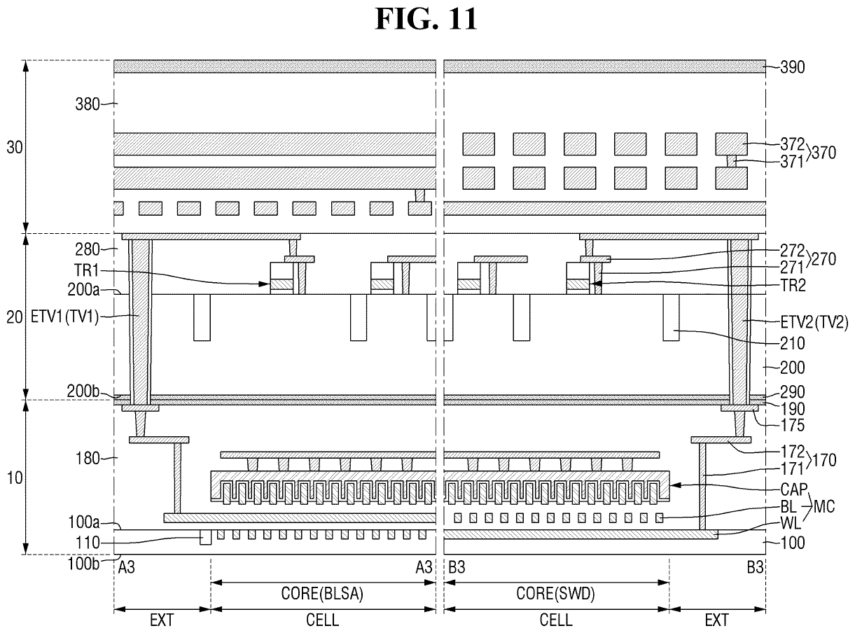

FIG. 10 is an enlarged layout view of a region R2 (of FIG. 2) of a semiconductor device according to some embodiments of the present disclosure. FIG. 11 is a cross-sectional view taken along lines A3-A3 and B3-B3 of FIG. 10. For convenience, the embodiment of FIGS. 10 and 11 will be hereinafter described, focusing mainly on the differences with the embodiments of FIGS. 1 through 9.

Referring to FIGS. 1, 2, 10, and 11, at least some of through vias TV1 and TV2 overlap an extension area EXT.

For example, first through vias TV1 may include first extension area through vias ETV1 and third extension area through vias ETV3, and second through vias TV2 may include second extension area through vias ETV2 and fourth extension area through vias ETV4. The first extension area through vias ETV1 and the third extension area through vias ETV3 may overlap a part of the extension area EXT adjacent to a sense amplifier area BLSA. The second extension area through vias ETV2 and the fourth extension area through vias ETV4 may overlap a part of the extension area ETV adjacent to a sub-wordline driver area SWD.

FIG. 10 illustrates that all the first through vias TV1 and all the second through vias TV2 overlap the extension area EXT, but the present disclosure is not limited thereto. In some embodiments, some of the first through vias TV1 and some of the second through vias TV2 may overlap a cell area CELL.

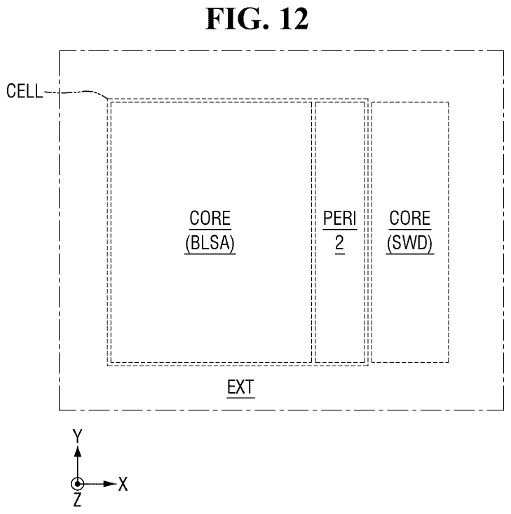

FIGS. 12 through 16 are layout views of semiconductor devices according to some embodiments of the present disclosure. For convenience, the embodiments of FIGS. 12 through 16 will be hereinafter described, focusing mainly on the differences with the embodiments of FIGS. 1 through 11.

Referring to FIG. 12, at least some core areas CORE and/or at least some second peripheral areas PERI2 may overlap an extension area EXT.

For example, a sense amplifier area BLSA and a second peripheral area PERI2 may overlap a cell area CELL, and a sub-wordline driver area SWD may overlap the extension area EXT. In this case, the size of circuit elements forming the sense amplifier area BLSA (e.g., the size of transistors forming a sense amplifier) can be further increased.

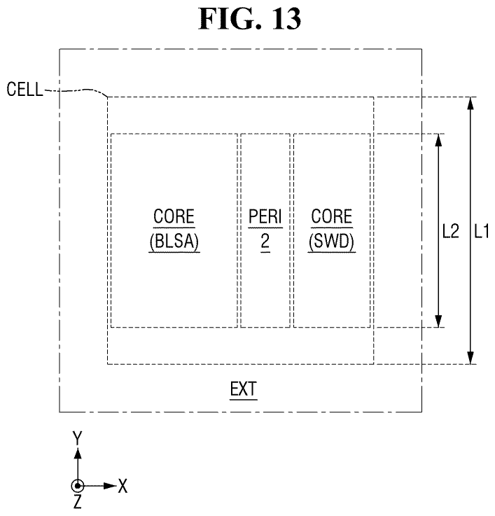

Referring to FIG. 13, a core area CORE and/or a second peripheral area PERI2 may be smaller in size than a second peripheral area PERI2.

For example, a cell area CELL may have a first length L1 in a second direction Y, and the core area CORE and the second peripheral area PERI2 may have a second length L2 in the second direction Y. The second length L2 may be less than the first length L1.

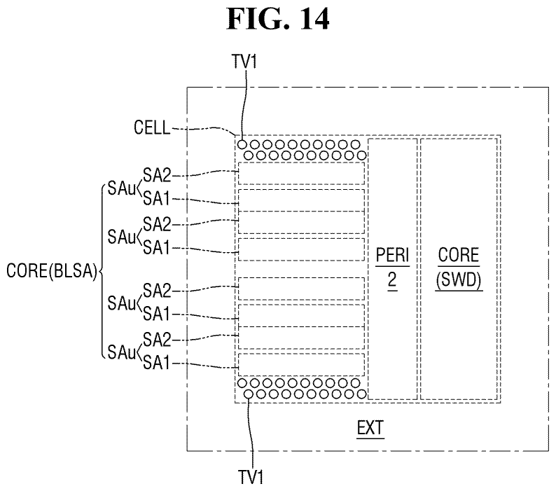

Referring to FIGS. 14 through 16, a sense amplifier area BLSA may include a plurality of unit sense amplifier areas SAu.

Each of the unit sense amplifier areas SAu may be provided as a differential sense amplifier receiving the voltages of a pair of bitlines BL as input, sensing the difference between the voltages of the bitlines BL, and amplifying the result of the sensing. For example, each of the unit sense amplifiers SAu may include a first sense amplifier area SA1, which senses the voltage of a bitline BL, and a second sense amplifier area SA2, which senses the voltage of another bitline BL. In some embodiments, the pair of bitlines BL may include a bitline and a complementary bitline, and the first and second sense amplifier areas SA1 and SA2 may cooperatively operate to sense a voltage difference between the bitline and the complementary bitline and amplify the voltage difference to determine whether data of the bitline is a low data or a high data. For example, the first sense amplifier SA1 may correspond to a pull-up circuit of a differential sense amplifier, and the second sense amplifier SA2 may correspond to a pull-down circuit of the differential sense amplifier.

In some embodiments, first through vias TV1 may be disposed on the periphery of the array of the unit sense amplifiers SAu. For example, as illustrated in FIG. 14, the first through vias TV1 may overlap a part of a cell area CELL that does not overlap the sense amplifier area BLSA.

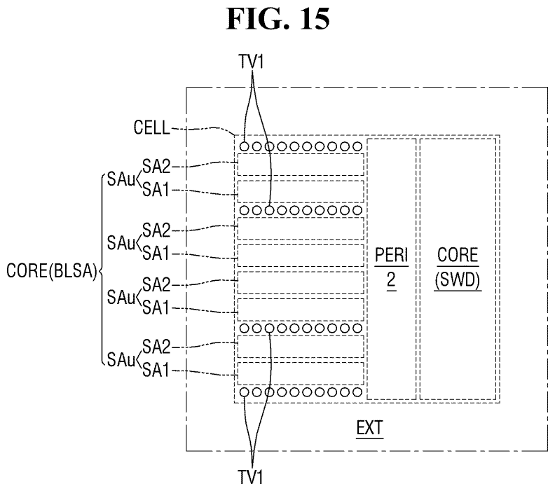

In some embodiments, the first through vias TV1 may be disposed between the unit sense amplifier areas SAu. For example, as illustrated in FIG. 15, the first through vias TV1 may be disposed between one unit sense amplifier area SAu and another unit sense amplifier area SAu.

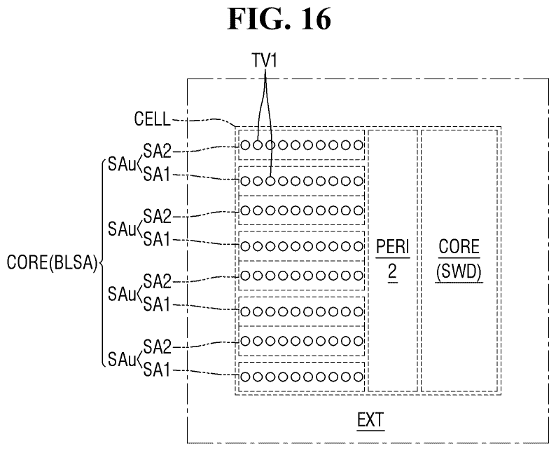

In some embodiments, the first through vias TV1 may be disposed on the unit sense amplifier areas SAu. For example, as illustrated in FIG. 16, the first through vias TV1 may be disposed in first sense amplifier areas SA1 and second sense amplifier areas SA2.

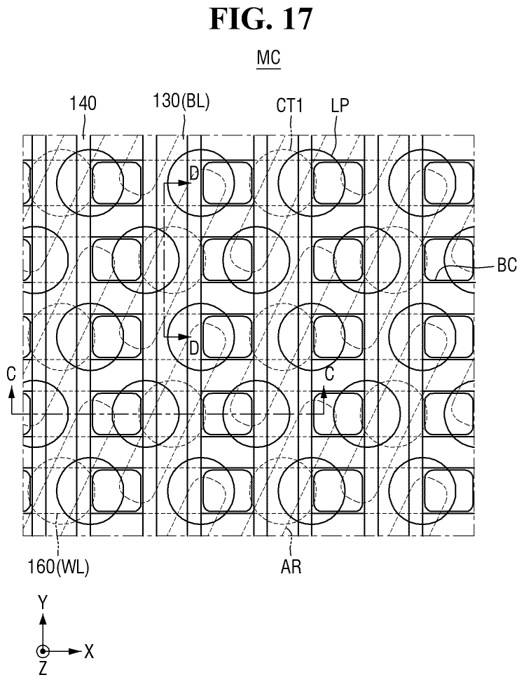

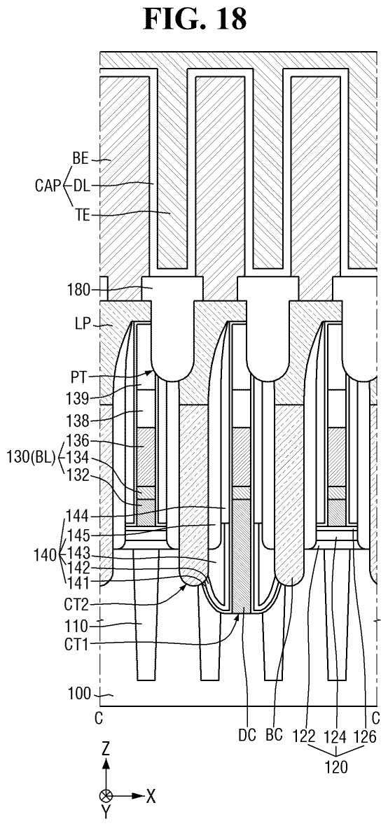

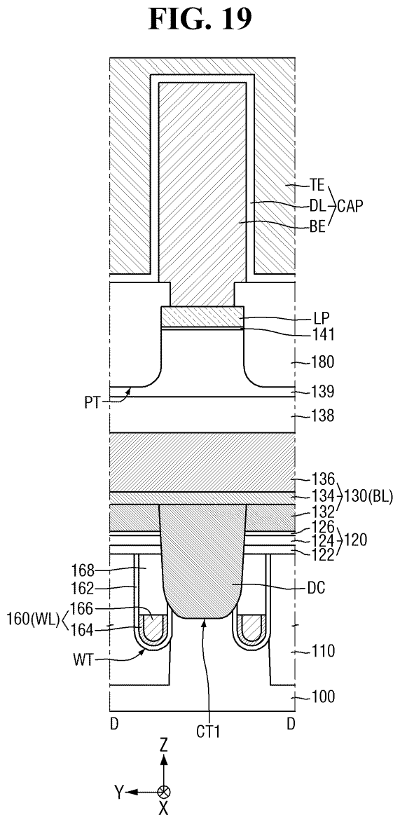

FIG. 17 is a layout view of a memory cell structure of a semiconductor device according to some embodiments of the present disclosure. FIG. 18 is a cross-sectional view taken along line C-C of FIG. 17. FIG. 19 is a cross-sectional view taken along line D-D of FIG. 17. For convenience, the embodiment of FIGS. 17 through 19 will be hereinafter described, focusing mainly on the differences with the embodiments of FIGS. 1 through 16.

Referring to FIGS. 17 through 19, a memory cell structure MC may include a lower substrate 100, lower device isolation patterns 110, a base insulating film 120, bitlines BL, first capping patterns 138 and 139, wordlines WL, direct contacts DC, spacer structures 140, buried contacts BC, a first barrier conductive film 150, landing pads LP, and a cell capacitor CAP.

The lower substrate 100 may include active regions AR. The active regions AR may be defined by the lower device isolation patterns 110 in the lower substrate 100. As the design rule of semiconductor memory devices decreases, the active regions AR may be formed as diagonal bars. For example, as illustrated in FIG. 17, the active regions AR may be in the form of bars extending in a direction other than first and second directions X and Y, over a plane including the first and second directions X and Y.

The active regions AR may be in the form of multiple bars extending in parallel to one another. The active regions AR may be arranged such that the center of one active region AR may be adjacent to an end part of another active region AR.

The active regions AR may include or may be doped with impurities and may thus function as source/drain regions. For example, first portions (e.g., middle portions) of the active regions AR may be connected to the bitlines BL by the direct contacts DC, and second portions (e.g., both end portions) of the active regions AR may be connected to the cell capacitor CAP by the buried contacts BC and the landing pads LP.

The base insulating film 120 may be formed on the lower substrate 100 and the lower device isolation patterns 110. The base insulating film 120 may be interposed between the lower substrate 100 and the bitlines BL and between the lower device isolation patterns 110 and the bitlines BL.

The base insulating film 120 may be a single film or may be a multifilm. For example, the base insulating film 120 may include first, second, and third insulating films 122, 124, and 126, which are sequentially stacked on the lower substrate 100 and the lower device isolation patterns 110. For example, the first insulating film 122 may include or may be a silicon oxide film, the second insulating film 124 may include or may be a silicon nitride film, and the third insulating film 126 may include or may be a silicon oxide film.

The bitlines BL may be formed on the lower substrate 100, the lower device isolation patterns 110, and the base insulating film 120. The bitlines BL may extend in the second direction Y. For example, the bitlines BL may extend diagonally across the active regions AR and perpendicularly across the wordlines WL. The bitlines BL may be spaced apart from one another by a predetermined distance and may extend in parallel to one another in the second direction Y.

The bitlines BL may include first conductive lines 130. The first conductive lines 130 may be single films or may be multifilms. For example, the first conductive lines 130 may include first conductive patterns 132, second conductive patterns 134, and third conductive patterns 136, which are sequentially stacked on the lower substrate 100. The first conductive patterns 132, the second conductive patterns 134, and the third conductive patterns 136 may include or may be formed of a conductive material such as, for example, polysilicon, TiN, TiSiN, W, tungsten silicide (WSi₂), and a combination thereof, but the present disclosure is not limited thereto. For example, the first conductive patterns 132 may include or may be formed of polysilicon, the second conductive patterns 134 may include or may be formed of TiSiN, and the third conductive patterns 136 may include or may be formed of W.

The first capping patterns 138 and 139 may be formed on the first conducive lines 130. The first capping patterns 138 and 139 may extend along the top surfaces of the first conductive lines 130. The first capping patterns 138 and 139 may be single films or may be multifilms. For example, the first capping patterns 138 and 139 may include first sub-capping patterns 138 and second sub-capping patterns 139, which are sequentially stacked on the first conductive lines 130. The first sub-capping patterns 138 and the second sub-capping patterns 139 may include or may be formed of an insulating material, for example, at least one of silicon oxide, silicon nitride, silicon oxynitride, silicon oxycarbonitride, and a combination thereof, but the present disclosure is not limited thereto. For example, the first sub-capping patterns 138 and the second sub-capping patterns 139 may include or may be formed of silicon nitride.

The wordlines WL may be formed on the lower substrate 100 and the lower device isolation patterns 110. The wordlines WL may extend in the first direction X. The wordlines WL may extend across the active regions AR between the direct contacts DC and the buried contacts BC. For example, the wordlines WL may extend diagonally across the active regions and perpendicularly across the bitlines BL. The word lines WL may be spaced apart from one another by a predetermined distance and may extend in parallel to one another in the first direction X.

The wordlines WL may include second conductive lines 160. The second conductive lines 160 may be single films or may be multifilms. For example, the second conductive lines 160 may include fourth conductive patterns 164 and fifth conductive patterns 166, which are sequentially stacked on the lower substrate 100. The fourth conductive patterns 164 and the fifth conductive patterns 166 may include or may be formed of at least one of, for example, a metal, polysilicon, and a combination thereof, but the present disclosure is not limited thereto. For example, the fourth conductive patterns 164 may include or may be formed of TiN, and the fifth conductive patterns 166 may include or may be formed of polysilicon doped with n-type impurities.

Wordline dielectric films 162 (i.e., gate insulating layers) may be interposed between the second conductive lines 160 and the active regions AR of the lower substrate 100. The wordline dielectric films 162 may include or may be formed of at least one of, for example, silicon oxide, silicon oxynitride, silicon nitride, and a high-k material having a greater dielectric constant than silicon oxide, but the present disclosure is not limited thereto.

Second capping patterns 168 may be formed on the second conductive lines 160. The second capping patterns 168 may extend along the top surfaces of the second conductive lines 160. The second capping patterns 168 may include or may be formed of at least one of, for example, silicon oxide, silicon nitride, silicon oxynitride, silicon oxycarbonitride, and a combination thereof, but the present disclosure is not limited thereto. The second capping patterns 168 may be single films or may be multifilms including a combination of various types of insulating materials.

In some embodiments, the wordlines WL may be buried in the lower substrate 100. For example, the lower substrate 100 may include gate trenches WT, which extend in the first direction X. The wordline dielectric films 162 may fill parts of the gate trenches WT. The second capping patterns 168 may fill the remaining parts of the gate trenches WT. The second capping patterns 168 may be disposed on the second conductive lines 160. In this case, the top surfaces of the second conductive lines 160 may be formed to be lower than the top surface of the lower substrate 100.

The direct contacts DC may be formed on the lower substrate 100 and the lower device isolation patterns 110. The direct contacts DC may connect the active regions AR of the lower substrate 100 and the bitlines BL with each other. For example, the lower substrate 100 may include first contact trenches CT1, which penetrate the base insulating film 120 to expose the first portions of the active regions AR. The direct contacts DC may be formed in the first contact trenches CT1 and may connect the active regions AR of the lower substrate 100 and the first conductive lines 130 with each other.

In some embodiments, the first contact trenches CT1 may expose the centers of the active regions AR. Accordingly, the direct contacts DC may be connected to the centers of the active regions AR. In some embodiments, parts of the first contact trenches CT1 may overlap parts of the lower device isolation patterns 110. Accordingly, the first contact trenches CT1 may expose not only parts of the active regions AR, but also parts of the lower device isolation patterns 110.

In some embodiments, the width of the direct contacts DC may be less than the width of the first contact trenches CT1. For example, as illustrated in FIG. 18, the direct contacts DC may be in contact with only parts of the lower substrate 100. The parts of the lower substrate 100 may be exposed by the first contact trenches CT1. In some embodiments, the width of the bitlines BL may also be less than the width of the first contact trenches CT1. For example, the width of the bitlines BL may be the same as the width of the direct contacts DC.

The direct contacts DC may include or may be formed of a conductive material, for example, at least one of polysilicon, TiN, TiSiN, W, WSi₂, and a combination thereof, but the present disclosure is not limited thereto. For example, the direct contacts DC may include or may be formed of polysilicon. The bitlines BL may be electrically connected to the active regions AR of the lower substrate 100 via the direct contacts DC. The active regions AR connected to the direct contacts DC may function as the source/drain regions of semiconductor devices including the wordlines WL.

The spacer structures 140 may be formed on opposite sides of the bitlines BL. The spacer structures 140 may extend along opposite sides of the first conductive lines 130 and opposite sides of the first capping patterns 138 and 139. In some embodiments, the height of the spacer structures 140 may be the same as, or less than, the height of the uppermost surfaces of the first capping patterns 138 and 139.

The spacer structures 140 may include or may be formed of an insulating material, for example, at least one of silicon oxide, silicon nitride, silicon oxynitride, silicon oxycarbonitride, and a combination thereof, but the present disclosure is not limited thereto. In some embodiments, the spacer structures 140 may be multifilms including a combination of various types of insulating materials. For example, the spacer structures 140 may include base spacers 141, first lower spacers 142, second lower spacers 143, first side spacers 144, and second side spacers 145.

The base spacers 141 may be formed on the opposite sides of the bitlines BL. For example, the base spacers 141 may extend conformally along the profiles of at least parts of the sides of the first conductive lines 130 and the opposite sides of the first capping patterns 138 and 139. In some embodiments, the base spacers 141 may be innermost spacers of the spacer structures 140 that are in contact with the bitlines B1 and the direct contacts DC.

In some embodiments, the base spacers 141 may extend along the opposite sides of the bitlines B1 and the top surface of the base insulating film 120, in areas where the first contact trenches CT1 are not formed. In some embodiments, the base spacers 141 may extend along the opposite sides of the bitlines BL, the opposite sides of the direct contacts DC, and the first contact trenches CT1, in areas where the first contact trenches CT1 are formed.

The first lower spacers 142 may be formed on the base spacers 141 in the first contact trenches CT1. For example, the first lower spacers 142 may extend conformally along the profiles of the base spacers 141 in the first contact trenches CT1.

The second lower spacers 143 may be formed on the first lower spacers 142 in the first contact trenches CT1. For example, the second lower spacers 143 may fill parts of the first contact trenches CT1 that are not filled with the base spacers 141 and the first lower spacers 142.

The first side spacers 144 may be formed on the outer sides of the base spacers 141. The first side spacers 144 may be formed on the first lower spacers 142 and the second lower spacers 143. For example, the first side spacers 144 may extend conformally along the profiles of parts of the sides of the first capping patterns 138 and 139 and the sides of the first conductive lines 130.

The second side spacers 145 may be formed on the outer sides of the first side spacers 144. The second side spacers 145 may be formed on the second lower spacers 143. For example, the second side spacers 145 may extend conformally along the profiles of parts of the sides of the first capping patterns 138 and 139 and the sides of the first conductive lines 130. In some embodiments, the second side spacers 145 may be outermost spacers of the spacer structures 140 that are in contact with the buried contacts BC.

In some embodiments, the bottom surfaces of the second side spacers 145 may be formed to be lower than uppermost surfaces of the second lower spacers 143.

The base spacers 141, the first lower spacers 142, the second lower spacers 143, the first side spacers 144, and the second side spacers 145 may include or may be formed of an insulating material, for example, at least one of silicon oxide, silicon nitride, silicon oxynitride, silicon oxycarbonitride, and a combination thereof, but the present disclosure is not limited thereto.

In some embodiments, the first lower spacers 142 may include or may be formed of a different material from the base spacers 141 and/or the second lower spacers 143. For example, the first lower spacers 142 may include or may be formed of an insulating material with a less dielectric constant than the base spacers 141 and/or the second lower spacers 143. For example, the first lower spacers 142 may include or may be formed of silicon oxide, and the base spacers 141 and the second lower spacers 143 may include or may be formed of silicon nitride.

In some embodiments, the first side spacers 144 may include or may be formed of a different material from the base spacers 141 and/or the second side spacers 145. For example, the first side spacers 144 may include or may be formed of an insulating material with a less dielectric constant than the base spacers 141 and/or the second side spacers 145. For example, the first side spacers 144 may include or may be formed of silicon oxide, and the base spacers 141 and the second side spacers 145 may include or may be formed of silicon nitride.

The buried contacts BC may be formed on the lower substrate 100 and the lower device isolation patterns 110. The buried contacts BC may connect the active regions AR of the lower substrate 100 and the landing pads LP with each other. For example, the lower substrate 100 may include second contact trenches CT2, which penetrate the base insulating film 120 to expose the second portions of the active regions AR. The buried contacts BC may be formed in the second contact trenches CT2 and may thus connect the active regions AR of the lower substrate 100 and the landing pads LP with each other.

In some embodiments, the second contact trenches CT2 may expose opposite ends of each of the active regions AR. Accordingly, in each active region AR, two buried contacts BC may be connected to the opposite ends of each active regions AR, respectively. In some embodiments, parts of the second contact trenches CT2 may overlap parts of the lower device isolation patterns 110. Accordingly, the second contact trenches CT2 may expose not only parts of the active regions AR, but also parts of the lower device isolation patterns 110.

The buried contacts BC may be formed on opposite sides of the bitlines BL. The buried contacts BC may be spaced apart from the bitlines BL by the spacer structures 140. For example, as illustrated in FIG. 18, the buried contacts BC may extend along parts of the outer sides of the spacer structures 140. Rows of buried contacts BC that are arranged in the first direction X may be spaced apart from one another by the bitlines BL and the spacer structures 140, which extend in the second direction Y. In some embodiments, the top surfaces of the buried contacts BC may be formed to be lower than the top surfaces of the first capping patterns 138 and 139.

The buried contacts BC may form a plurality of isolated areas, which are spaced apart from one another. For example, as illustrated in FIG. 17, the buried contacts BC may be interposed between the bitlines BL and between the wordlines WL. In some embodiments, the buried contacts BC may be arranged in a lattice structure.

The buried contacts BC may include or may be formed of a conductive material, for example, at least one of polysilicon, TiN, TiSiN, W, WSi₂, and a combination thereof, but the present disclosure is not limited thereto. For example, the buried contacts BC may include or may be formed of polysilicon. The landing pads LP may be electrically connected to the active regions AR of the lower substrate 100 via the buried contacts BC. The active regions AR connected to the buried contacts BC may function as source/drain regions of semiconductor devices including the wordlines WL.

The landing pads LP may be formed on the buried contacts BC. The landing pads LP may be electrically connected to the buried contacts BC. In some embodiments, the landing pads LP may overlap at least parts of the buried contacts BC. For example, as illustrated in FIGS. 17 and 18, parts of the landing pads LP may overlap the buried contacts BC, and parts of the landing pads LP may overlap parts of the spacer structures 140 and parts of the first capping patterns 138 and 139.

The landing pads LP may include or may be formed of a conductive material, for example, at least one of polysilicon, TiN, TiSiN, W, WSi₂, and a combination thereof, but the present disclosure is not limited thereto. For example, the landing pads LP may include or may be formed of W. The cell capacitor CAP may be electrically connected to the active regions AR of the lower substrate 100 via the buried contacts BC and the landing pads LP.

The landing pads LP may form a plurality of isolated areas, which are spaced apart from one another. For example, as illustrated in FIGS. 18 and 19, pad trenches PT, which define the landing pads LP, may be formed. The pad trenches PT may extend from the top surfaces of the landing pads LP, and the bottom surfaces of the pad trenches PT may be formed to be lower than the top surfaces of the spacer structures 140. At least parts of the pad trenches PT may overlap parts of the spacer structures 140. For example, the pad trenches PT may overlap parts of the spacer structures 140 and parts of the first capping patterns 138 and 139. In this manner, the landing pads LP may be isolated from one another by the pad trenches PT.

In some embodiments, a lower insulating structure 180, which fills the pad trenches PT, may be formed. The lower insulating structure 180 may include or may be formed of an insulating material, for example, at least one of silicon oxide, silicon oxynitride, silicon nitride, and a low-k dielectric material having a smaller dielectric constant than silicon oxide, but the present disclosure is not limited thereto. The landing pads LP may be electrically isolated from one another by the lower insulating structure 180.

In some embodiments, the landing pads LP may be arranged in a honeycomb structure. Accordingly, the degree of integration of the semiconductor device according to some embodiments of the present disclosure can be further improved.

The cell capacitor CAP may be formed on the lower insulating structure 180 and the landing pads LP. The cell capacitor CAP may be connected to the top surfaces of the landing pads LP. For example, the lower insulating structure 180 may be patterned to expose at least parts of the top surfaces of the landing pads LP. The cell capacitor CAP may be connected to at least parts of the top surfaces of the landing pads LP that are exposed by the lower insulating structure 180. Accordingly, the cell capacitor CAP may be electrically connected to the active regions AR of the lower substrate 100 via the buried contacts BC and the landing pads LP. The operation of the cell capacitor CAP may be controlled by the bitlines BL and the wordlines WL to store data.

In some embodiments, the cell capacitor CAP may include lower electrodes BE, a capacitor dielectric film DL, and an upper electrode TE, which are sequentially stacked on the landing pads LP. The cell capacitor CAP may store electric charges in the capacitor dielectric film DL, using the difference in electric potential between the lower electrodes BE and the upper electrode TE.

The lower electrodes BE and the upper electrode TE may include or may be formed of, for example, doped polysilicon, a metal, or a metal nitride, but the present disclosure is not limited thereto. The capacitor dielectric film DL may include or may be formed of, for example, silicon oxide or a high-k material, but the present disclosure is not limited thereto.

A method of fabricating a semiconductor device according to some embodiments of the present disclosure will be hereinafter described with reference to FIGS. 1 through 29.

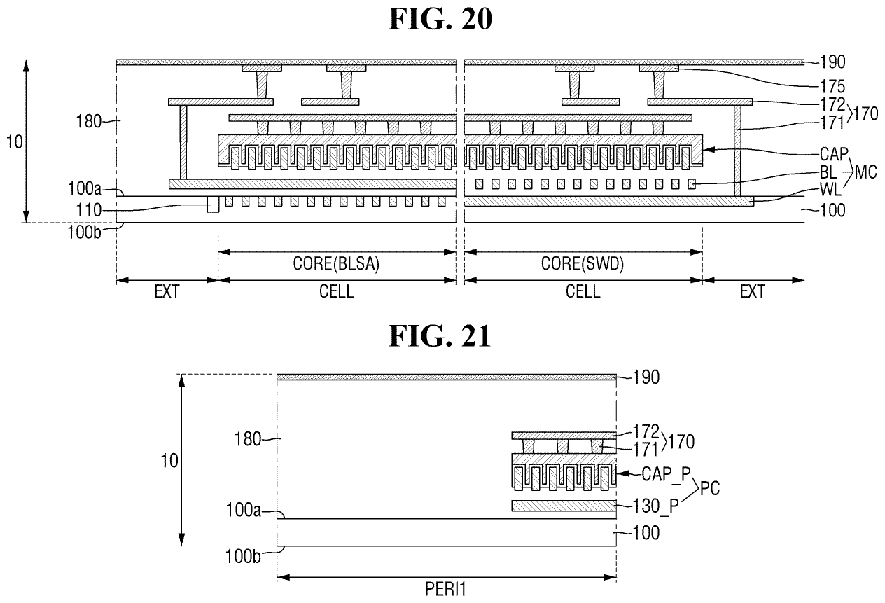

FIGS. 20 through 29 are cross-sectional views illustrating a method of fabricating a semiconductor device according to some embodiments of the present disclosure. For convenience, the embodiment of FIGS. 20 through 29 will be hereinafter described, focusing mainly on the differences with the embodiments of FIGS. 1 through 19.

Referring to FIGS. 20 and 21, a lower bonding structure 10 is formed.

For example, a lower substrate 100 may be provided. Thereafter, lower device isolation patterns 110 may be formed in the lower substrate 100. Thereafter, a memory cell structure MC and a power capacitor structure PC may be formed on a first surface 100a of the lower substrate 100. Thereafter, a lower insulating structure, which covers the memory cell structure MC and the power capacitor structure PC, and a lower wiring structure 170, which is electrically connected to the memory cell structure MC and the power capacitor structure PC, may be formed.

In some embodiments, a first bonding insulating film 190, which covers the lower insulating structure 180, may be formed. The first bonding insulating film 190 may include or may be formed of an oxide film (e.g., a SiO₂ film), but the present disclosure is not limited thereto.

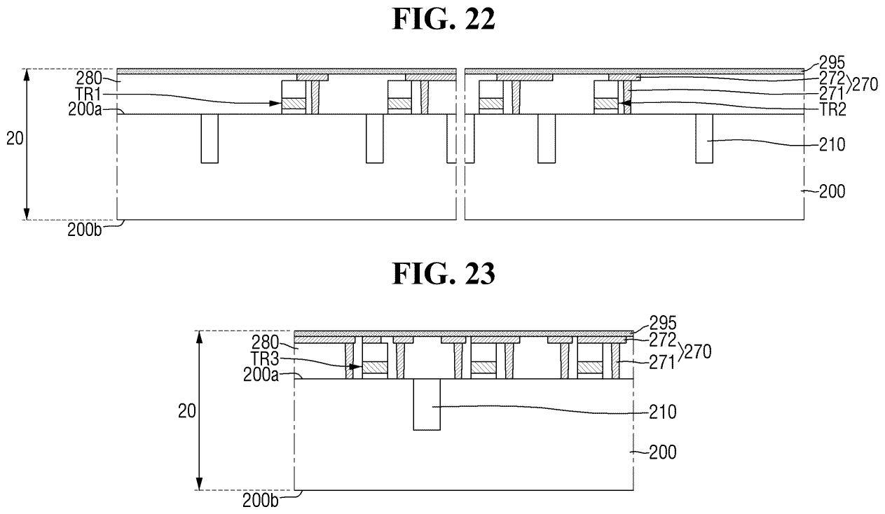

Referring to FIGS. 22 and 23, an upper bonding structure 20 is formed.

For example, an upper substrate 200 may be provided. Thereafter, upper device isolation patterns 210 may be formed in the upper substrate 200. Thereafter, first circuit elements TR1, second circuit elements TR2, and third circuit elements TR3 may be formed on a third surface 200a of the upper substrate 200. Thereafter, an upper insulating structure 280, which covers the first circuit elements TR1, the second circuit elements TR2, and the third circuit elements TR3, and an upper wiring structure 270, which is electrically connected to the first circuit elements TR1, the second circuit elements TR2, and the third circuit elements TR3, may be formed.

In some embodiments, a third bonding insulating film 295, which covers the upper insulating structure 280, may be further formed. The third bonding insulating film 295 may include or may be an oxide film (e.g., a SiO₂ film), but the present disclosure is not limited thereto.

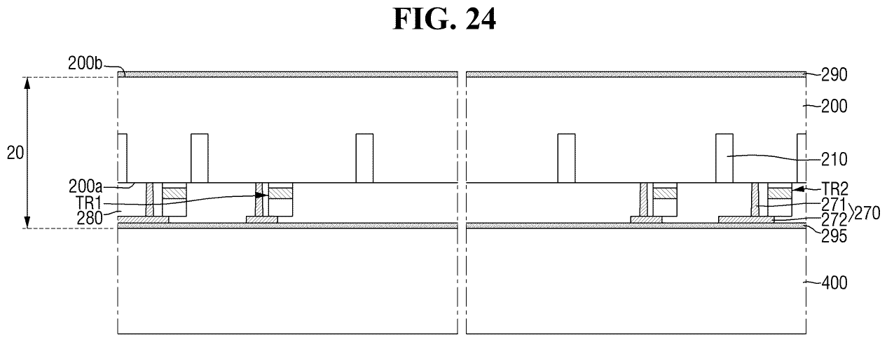

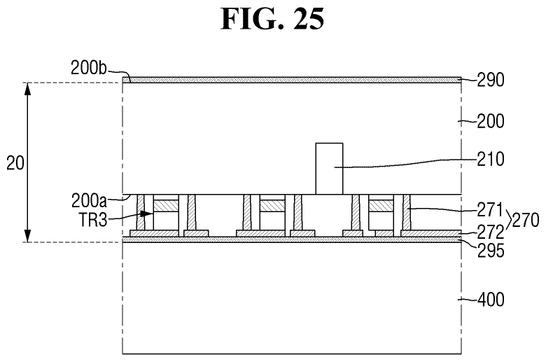

Referring to FIGS. 24 and 25, the upper bonding structure 20 is bonded onto a carrier substrate 400.

For example, the upper bonding structure 20 may be attached onto the carrier substrate 400 via the third bonding insulating film 295. The carrier substrate 400 may be provided as a support substrate supporting the upper bonding structure 20 in subsequent processes. As the upper bonding structure 20 is attached to the carrier substrate 400, the resulting structure may be turned upside down such that a fourth surface 200b of the upper substrate 200 may face upward.

In some embodiments, a back-lapping process may be performed on the fourth surface 200b of the upper substrate 200. As a result, the thickness of the upper substrate 200 may be reduced.

In some embodiments, a second bonding insulating film 290, which covers the fourth surface 200b of the upper substrate 200, may be further formed. The second bonding insulating film 290 may include or may be an oxide film (e.g., a SiO₂ film), but the present disclosure is not limited thereto.

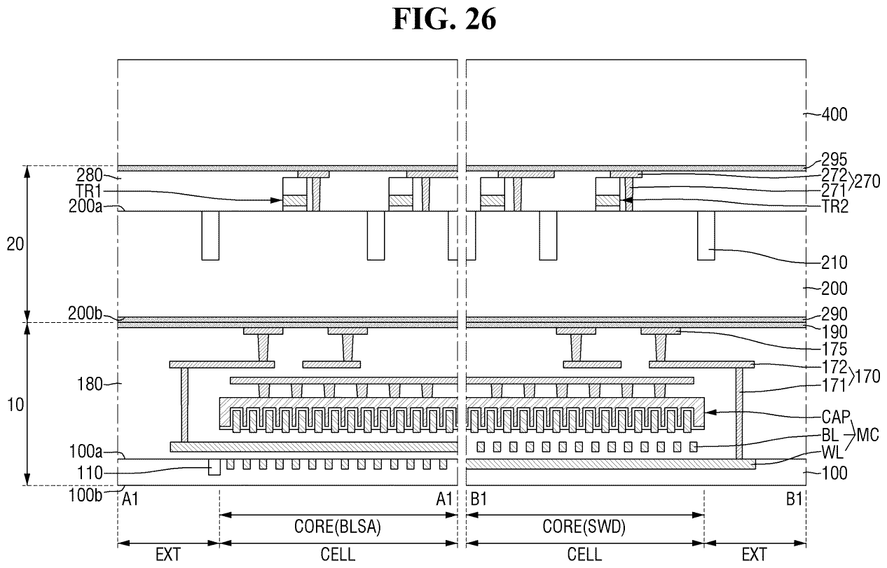

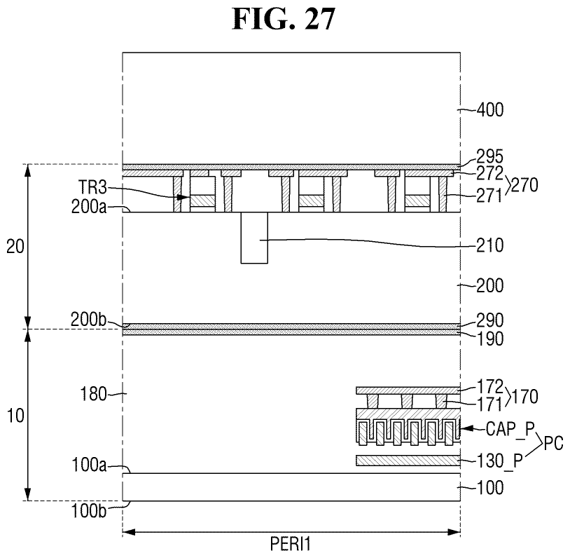

Referring to FIGS. 26 and 27, the upper bonding structure 20 is stacked on the lower bonding structure 10.

The upper bonding structure 20 may be bonded onto the lower bonding structure 10 in an F2B bonding method. For example, the upper bonding structure 20 may be stacked on the lower bonding structure 10 such that the back side (i.e., the fourth surface 200b) of the upper substrate 200 may face the front side of the lower substrate 100 (i.e., the first surface 100a).

In some embodiments, the lower and upper bonding structures 10 and 20 may be bonded together in a dielectric bonding method. For example, the first bonding insulating film 190 of the lower bonding structure 10 and the second bonding insulating film 290 of the upper bonding structure 20 may be attached together.

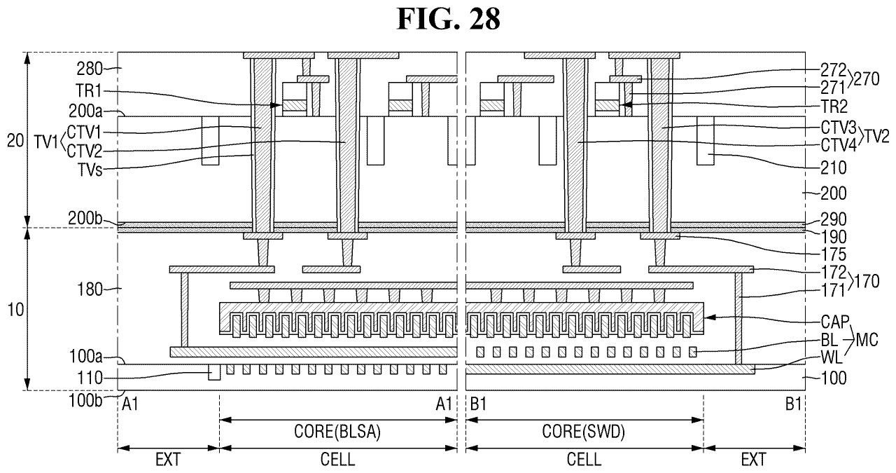

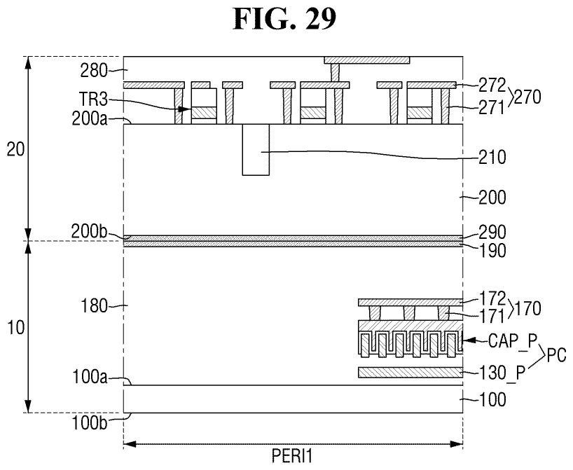

Referring to FIGS. 28 and 29, a plurality of through vias TV1 and TV2, which penetrate the upper substrate 200, are formed.

For example, the carrier substrate 400 and the third bonding insulating film 295 may be removed after the stacking of the upper bonding structure 20 on the lower bonding structure 10. Thereafter, through via holes (e.g., “TVh” of FIG. 5), which sequentially penetrate the upper insulating structure 280, the upper substrate 200, the second bonding insulating film 290, and the first bonding insulating film 190, may be formed. The through vias TV1 and TV2 may be formed in the through via holes and may sequentially penetrate the upper insulating structure 280, the upper substrate 200, the second bonding insulating film 290, and the first bonding insulating film 190.

Thereafter, an upper wiring structure 270, which connects the first circuit elements TR1, the second circuit elements TR2, and the third circuit elements TR3 of the upper bonding structure 20 and the through vias TV1 and TV2 with each other, may be formed. Accordingly, the through vias TV1 and TV2 may electrically connect the lower wiring structure 170 and the upper wiring structure 270 with each other.

Thereafter, referring to FIGS. 4 through 6, a connection structure 30 is formed on the upper bonding structure 20. In this manner, the semiconductor device of FIGS. 1 through 6 may be obtained.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

1. A semiconductor device comprising:
a lower substrate;
a memory cell structure including:
a wordline on the lower substrate;
a bitline disposed on the lower substrate and intersecting the wordline; and
a cell capacitor connected to the lower substrate;
an upper substrate having a back side adjacent to the lower substrate and a front side opposite to the back side;
a circuit element disposed on the front side of the upper substrate and overlapping the memory cell structure in a vertical direction; and
a through via penetrating the upper substrate and electrically connecting the memory cell structure and the circuit element with each other.

2. The semiconductor device of claim 1, further comprising:
a lower insulating structure disposed on the lower substrate and covering the memory cell structure; and
a lower wiring structure disposed in the lower insulating structure and electrically connecting the memory cell structure and the through via with each other.

3. The semiconductor device of claim 2, further comprising:
a bonding insulating film interposed between the lower insulating structure and the upper substrate.

4. The semiconductor device of claim 3,
wherein the bonding insulating film includes a first oxide film disposed on a bottom surface of the upper substrate and a second oxide film disposed on an upper surface of the lower insulating structure, and
wherein the first oxide film is attached to the second oxide film in oxide bonding.

5. The semiconductor device of claim 2, wherein:
the lower substrate includes:
a cell area on which the wordline, the bitline, and the cell capacitor are disposed; and
an extension area adjacent to the cell area, an end portion of the wordline and
an end portion of the bitline being disposed on the extension area, and
the lower wiring structure is connected to the end portion of the wordline and the end portion of the bitline on the extension area.

6. The semiconductor device of claim 1, further comprising:
a through spacer disposed between the upper substrate and the through via and extending along a side of the through via.

7. The semiconductor device of claim 1,
wherein a width of the through via gradually decreases in a direction from the upper substrate to the lower substrate.

8. The semiconductor device of claim 1,
wherein the circuit element forms a sense amplifier electrically connected to the bitline.

9. The semiconductor device of claim 1,
wherein the circuit element forms a sub-wordline driver electrically connected to the wordline.

10. The semiconductor device of claim 1, wherein:
the lower substrate includes a trench, and
the wordline is disposed in the trench.

11. A semiconductor device comprising:
a lower substrate including a cell area and an extension area adjacent to the cell area;
a memory cell structure including:
a wordline disposed on the cell area and extending from the cell area in a first direction beyond an outer boundary of the cell area into the extension area, an end portion of the wordline being disposed on the extension area;
a bitline disposed on the cell area and extending from the cell area in a second direction beyond the outer boundary of the cell area into the extension area, an end portion of the bitline being disposed on the extension area; and
a cell capacitor disposed on the cell area;
a lower insulating structure disposed on the lower substrate and covering the memory cell structure;
a lower wiring structure disposed in the lower insulating structure and connected to the end portion of the wordline and the end portion of the bitline on the extension area;
a bonding insulating film on the lower insulating structure;
an upper substrate disposed on the bonding insulating film and having a back side adjacent to the lower substrate and a front side opposite to the back side;
a plurality of circuit elements on the front side of the upper substrate;
an upper insulating structure disposed on the upper substrate and covering the plurality of circuit elements;
an upper wiring structure disposed in the upper insulating structure and connected to the plurality of circuit elements; and
a plurality of through vias penetrating the upper substrate and the bonding insulating film and electrically connecting the lower wiring structure and the upper wiring structure with each other.

12. The semiconductor device of claim 11,
wherein at least some of the plurality of circuit elements overlap the cell area in a vertical direction.

13. The semiconductor device of claim 11, wherein:
a first group of the plurality of circuit elements forms a sense amplifier electrically connected to the bitline, and
a second group of the plurality of circuit elements forms a sub-wordline driver electrically connected to the wordline.

14. The semiconductor device of claim 11,
wherein at least some of the plurality of through vias overlap the cell area.

15. The semiconductor device of claim 11,
wherein at least some of the plurality of through vias overlap the extension area.

16. The semiconductor device of claim 11, further comprising:
a connection structure disposed on the upper insulating structure and electrically connected to the upper wiring structure.

17. A semiconductor device comprising:
a lower substrate including a gate trench, wherein the gate trench extends in a first direction;
a memory cell structure including:
a wordline disposed in the gate trench and extending in the first direction in the gate trench;
a bitline disposed on the lower substrate and extending in a second direction intersecting the first direction; and
a cell capacitor disposed on the bitline and connected to the lower substrate;
an upper substrate having a back side adjacent to the lower substrate, and a front side opposite to the back side, the upper substrate including a sense amplifier area and a sub-wordline driver area;
a first circuit element disposed on the front side of the sense amplifier area;
a second circuit element disposed on the front side of the sub-wordline driver area;
a first through via penetrating the upper substrate and electrically connecting the bitline and the first circuit element with each other; and
a second through via penetrating the upper substrate and electrically connecting the wordline and the second circuit element with each other,
wherein at least one of the first circuit element and the second circuit element overlaps the memory cell structure in a vertical direction.

18. The semiconductor device of claim 17, further comprising:
a lower device isolation pattern defining each of a plurality of active regions in the lower substrate,
wherein:
the bitline is connected to a first portion of a corresponding active region of the active regions,
the cell capacitor is connected to a second portion of the corresponding active region, and
the wordline is interposed between the first portion and the second portion.

19. The semiconductor device of claim 17, further comprising:
a lower insulating structure disposed on the lower substrate and covering the memory cell structure; and
a lower wiring structure disposed in the lower insulating structure electrically connecting the bitline and the first through via with each other, and electrically connecting the wordline and the second through via with each other.

20. The semiconductor device of claim 19, further comprising:
a bonding insulating film interposed between the lower insulating structure and the upper substrate.

21-25. (canceled)
